(19) United States
(12) Patent Application Publication
(10) Pub. No.: US 2021/0403757 A1
(43) Pub. Date: Dec. 30, 2021

(54) POLISHING MATERIAL AND POLISHING METHOD

(71) Applicant: AGC Inc., Tokyo (JP)

(72) Inventor: Yuzo OKAMURA, Chiyoda-ku (JP)

(73) Assignee: AGC Inc., Tokyo (JP)

(21) Appl. No.: 17/358,623

(22) Filed: Jun. 25, 2021

(30) Foreign Application Priority Data
Jun. 29, 2020 (JP) 2020-111477

(51) Int. Cl. C09G 1/02; B24B 37/24; H01L 21/304

(52) U.S. Cl. CPC C09G 1/02; H01L 21/304; B24B 37/245

(57) ABSTRACT

A polishing material which controls a polishing rate of a silicon surface is provided. A polishing material including abrasive grains and a compound represented by a Formula (1).

R—O-(AO)ₘ—H Formula (1)

In the Formula (1), R is an organic group including a conjugated system and may include a heteroatom in a carbon skeleton, and C1/(C1+C2)≥0.4 holds, where C1 is the number of atoms constituting the conjugated system and C2 is the number of atoms not constituting the conjugated system among atoms constituting the carbon skeleton,

AO represents an oxyalkylene group, and a plurality of the AOs may be the same as or different from each other, and

n is an integer of 2 to 200.

### CROSS REFERENCE TO RELATED APPLICATIONS

This application is based upon and claims the benefit of priority from Japanese patent application No. 2020-111477, filed on Jun. 29, 2020, the disclosure of which is incorporated herein in its entirety by reference.

### BACKGROUND

The present disclosure relates to a polishing material and a polishing method, and more particularly to a polishing material and a polishing method for chemical mechanical polishing in manufacturing semiconductor integrated circuits.

Recently, as semiconductor integrated circuits have become highly integrated and highly functional, microfabrication techniques for microfabricating and densifying semiconductor elements have been developed. In the related art, in the manufacture of a semiconductor integrated circuit apparatus (hereinafter also referred to as a semiconductor device), in order to prevent problems such as a sufficient resolution cannot be obtained due to unevenness (level difference) of a layer surface exceeding a depth of focus of lithography, planarization of an interlayer insulating film, buried wiring, etc. has been performed using Chemical Mechanical Polishing (hereinafter referred to as CMP). As demands for high definition and microfabrication of elements have become more pressing, the importance of high planarization by the CMP has been increasing.

Recently, in the manufacture of a semiconductor device, in order to achieve a further degree of microfabrication of the semiconductor element, an isolation method (Shallow Trench Isolation: hereinafter referred to as STI) using a shallow trench having a small isolation width has been introduced.

The STI is a method for forming an electrically insulated element region by forming a trench (groove) in a silicon substrate and embedding an insulating film in the trench. An example of the STT will be described with reference to FIGS. 1A and 1B. In the example of FIGS. 1A and 1B, first, as shown in FIG. 1A, after the element region of a silicon substrate 1 is masked with a silicon nitride film 2 or the like, a trench 3 is formed in the silicon substrate 1, and an insulating film such as a silicon dioxide film 4 is deposited to fill the trench 3. Then, the silicon dioxide film 4 on the silicon nitride film 2, which is a projection, is polished and removed by the CMP while leaving the silicon dioxide film 4 in the trench 3, which is a recess, thereby obtaining an element isolation structure in which the silicon dioxide film 4 is buried in the trench 3, as shown in FIG. 1B.

In such CMP in the STI, the progress of the polishing can be stopped when the silicon nitride film is exposed by increasing a selection ratio (i.e., a ratio of a polishing rate of the silicon dioxide film to a polishing rate of the silicon nitride film) of the silicon dioxide film to the silicon nitride film. In the polishing method using the silicon nitride film as a stopper film, a smoother surface can be obtained as compared with the normal polishing method.

In addition, in the CMP technique of recent years, it has been studied to suppress the progress of the polishing on the silicon substrate surface instead of using the stopper film. It has also been studied to remove not only a silicon dioxide film but also a silicon nitride film.

When a silicon (including polysilicon and amorphous silicon) surface is used as the stopper film, it is necessary to reduce the polishing rate of silicon for the film to be removed.

For example, Japanese Patent No. 5628802 discloses a CMP slurry containing a nonionic surfactant including a hydrophilic part and a lipophilic part, and the hydrophilic part has a number average molecular weight of 500 g/mol or more. According to Japanese Patent No. 5628802, the nonionic surfactant controls the polishing rate of the surface of the silicon-containing substrate.

Japanese Patent No. 5444625 discloses a CMP polishing liquid for polishing silicon oxide of a substrate including the silicon oxide and silicon nitride or polysilicon as a stopper film, which contains (1) a surfactant having an HLB≥17.5, (2) an inorganic polishing material, and (3) a water-soluble organic polymer other than the surfactant. According to Japanese Patent No. 5444625, it is possible to achieve high-speed polishing of the silicon oxide film by the surfactant while maintaining a high selection ratio of the polishing rate of the silicon oxide film to that of the polysilicon.

### SUMMARY

The present inventor has found that when a patterned wafer including a patterned trench is formed on a silicon substrate and an insulating film in the trench is polished, even when the surfactant disclosed in Japanese Patent No. 5628802 or Japanese Patent No. 5444625 is used, a silicon surface may be polished, and thus the selectivity between the silicon surface and the insulating film may be insufficient.

An object of the present disclosure is to provide a polishing material and a polishing method capable of suppressing a polishing rate of a silicon surface even in a patterned wafer.

According to an example aspect of the present disclosure, a polishing material including abrasive grains and a compound represented by a Formula (1).

R—O-(AO)ₘ—H Formula (1)

In the Formula (1), R is an organic group including a conjugated system and may include a heteroatom in a carbon skeleton, and C1/(C1+C2)≥0.4 holds, where C1 is the number of atoms constituting the conjugated system and C2 is the number of atoms not constituting the conjugated system among atoms constituting the carbon skeleton,

AO represents an oxyalkylene group, and a plurality of the AOs may be the same as or different from each other, and

n is an integer of 2 to 200.

In the above polishing material, the R may include an aryl group.

In the above polishing material, in an R—O bond of the Formula (1), an R-side atom may be a carbon atom constituting the aryl group.

In the above polishing material, the R may be a hydrocarbon group.

In the polishing material, a compound expressed by the Formula (1) may include an HLB value of 12 to 20.

In the polishing material, the abrasive grains may be metal oxide particles.

The above polishing material may further include a polymer.

In the above polishing material, the polymer includes an anionic polymer.

In the polishing material, the anionic polymer may include an aryl group.

In the above polishing material, pH may be 2 to 7.

The above polishing material can be used to expose a patterned surface including a silicon surface on a surface.

Another example aspect of the present disclosure is a polishing method for bringing a surface to be polished into contact with a polishing pad while supplying a polishing material and performing polishing by a relative motion of the surface to be polished and the polishing pad. The polishing method includes polishing the surface to be polished of a semiconductor substrate made of silicon oxide using the above polishing material as the polishing material.

In the polishing method, a patterned surface including a silicon surface may be exposed on a surface of the semiconductor substrate.

According to the present disclosure, it is possible to provide a polishing material and a polishing method capable of reducing a polishing rate of a silicon surface.

The above and other objects, features and advantages of the present disclosure will become more fully understood from the detailed description given hereinbelow and the accompanying drawings which are given by way of illustration only, and thus are not to be considered as limiting the present disclosure.

### BRIEF DESCRIPTION OF DRAWINGS

FIGS. 1A and 1B are cross-sectional views of an example of a semiconductor substrate to be polished by CMP in STI;

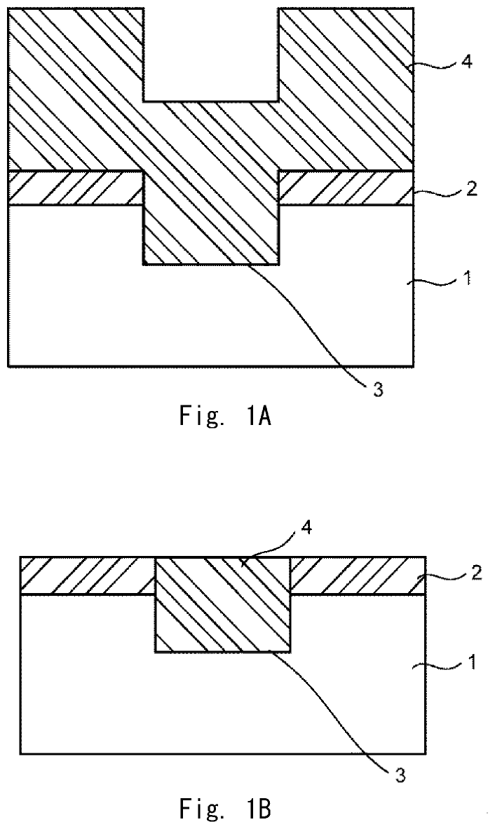

FIGS. 2A to 2D are schematic cross-sectional views for explaining an action of a polishing material according to the present disclosure;

FIG. 3 is a schematic diagram showing an example of a polishing device; and

FIG. 4 is a schematic cross-sectional view showing a substrate used for evaluating a pattern polishing rate and a polishing process in Example.

### DESCRIPTION OF EMBODIMENTS

Hereinafter, embodiments of the present disclosure will be described. The present disclosure is not limited to the following embodiments, and other embodiments may fall within the scope of the present disclosure as long as they are consistent with the spirit of the present disclosure.

In the present disclosure, the term “surface to be polished” means a surface of a polishing target to be polished and is, for example, a surface. In this specification, the surface in an intermediate stage appearing on a semiconductor substrate during the process of manufacturing a semiconductor device is also included in the term “surface to be polished”.

In the present disclosure, the term “silicon oxide” is specifically silicon dioxide, but the present disclosure is not limited to this, and the term “silicon oxide” also includes silicon oxide other than silicon dioxide.

In the present disclosure, the term “selection ratio” means a ratio (R_{A}/R_{B}) of a polishing rate (R_{A}) of a film A (e.g., a stopper film) to a polishing rate (R_{B}) of a film _{B} (e.g., a polishing target film).

In addition, the term “to” between numerical values indicating a numerical range means that the numerical values described before and after “to” are included as a lower limit value and an upper limit value in the numerical range.

For clarity of description, the following description and drawings have been simplified as appropriate. Moreover, the scale of each member in the drawings may greatly differ for the sake of descriptions. In particular, projected and recessed shapes of the polished surface are extremely exaggerated.

### [Polishing Material]

A polishing material according to the present disclosure (hereinafter also referred to as the present polishing material) is characterized in containing abrasive grains and a compound represented by Formula (1) (hereinafter also referred to as a compound (1)).

R—O-(AO)ₘ—H Formula (1)

In this formula, R is an organic group containing a conjugated system and may include heteroatoms in a carbon skeleton. C1/(C1+C2)≥0.4 holds, where C1 is the number of atoms constituting the conjugated system and C2 is the number of atoms not constituting the conjugated system among the atoms constituting the carbon skeleton.

AO represents an oxyalkylene group, and a plurality of the AOs may be the same as or different from each other, and

n is an integer of 2 to 200.

According to the present disclosure, it is possible to obtain a polishing material capable of suppressing a polishing rate of a silicon surface while maintaining the polishing rate of a film to be polished even in a patterned wafer. Some of the actions of the polishing material are unknown, but it is speculated that they are as follows.

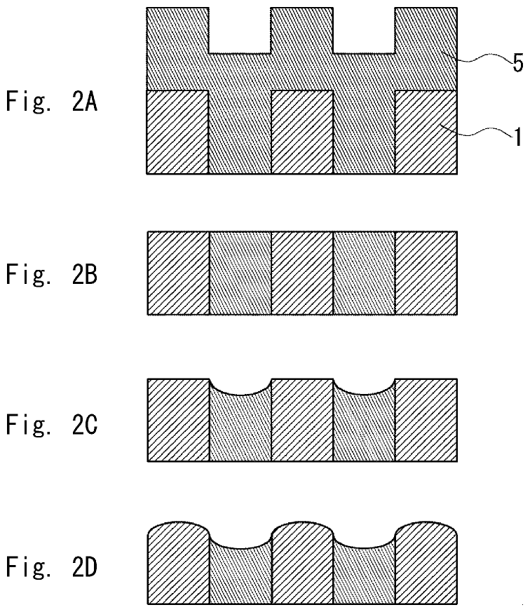

FIGS. 2A to 2D are schematic cross-sectional views for explaining an action of the polishing material. When polishing is started from the state shown in FIG. 2A targeted for the state shown in FIG. 2B, in a normal manufacturing process, the polishing cannot be stopped at the moment when the state shown in FIG. 2B is reached, and in many cases the polishing further advances. At this time, the silicon surface may be scraped.

On the other hand, for example, it is stated in Japanese Patent No. 5628802 that when the nonionic surfactant described in Japanese Patent No. 5628802 is used, the nonionic surfactant coats the silicon surface to thereby suppress the polishing of the silicon surface. However, in the case of a patterned wafer in which a silicon nitride film or a silicon oxide film and silicon are arranged in a pattern, as a result of an increase in the selection ratio of the silicon nitride film or the silicon oxide film to the silicon, as shown in FIG. 2C, the surface to be polished may be excessively ground and recesses (dishing) may be formed on the surface. If the polishing processing further advances from this state, it is estimated that a large load is applied to the edge of the silicon surface. As a result, as shown in FIG. 2D, it is presumed that the silicon surface is ground from the edge of the silicon surface and polishing of the silicon surface advances. The compound (1) contained in the present polishing material includes a conjugated system. It is presumed that the conjugated system of the compound (1) is adsorbed to the film surface by the interaction of it electrons of the conjugated system with the silicon nitride or the silicon oxide to be polished. It is therefore presumed that the polishing rate of the polishing target film is reduced and the formation of dishing is prevented or minimized. Further, since a polyoxyalkylene group of the compound (1) has a high affinity with silicon, it is presumed that the conjugated system of the compound (1) adsorbs the silicon nitride or the silicon oxide, and the polyoxyalkylene group is adsorbed to the silicon substrate to protect the edge of the silicon surface.

Given these situations, it is possible to achieve an effect that the polishing rate of the silicon surface is controlled even in the patterned wafer.

The polishing material according to the present disclosure contains at least abrasive grains and the compound (1), and may further contain other components within the scope of the effects of the present disclosure. Hereinafter, each component that can be contained in the polishing material will be described in detail.

### <Compound (1)>

The polishing material contains a compound represented by the Formula (1).

R is the organic group containing the conjugated system. Examples of the conjugated system include carbon-carbon double bonds, carbon-carbon triple bonds, aryl groups, and combinations thereof. Specific examples of such combinations include acetylene groups, ethylene groups, polyacetylene, phenylethenyl groups, biphenyl groups, terphenyl groups, etc. The compound (1) may contain one conjugated system or two or more conjugated systems. An example of including two or more conjugated systems includes a structure in which two or more aryl groups such as a cumylphenyl group are linked by an alkyl group.

These conjugated systems are adsorbed to the silicon nitride film and the silicon oxide film. The conjugated system preferably contains an aryl group in terms of the large surface to be covered and the stability of the compound (1). The aryl group may be an aromatic hydrocarbon ring group such as a phenyl group, a naphthyl group, an anthracenyl group, and a pyrenyl group, or may be an aromatic heterocyclic group such as a furyl group, a thiophenyl group, and a pyridyl group. The aryl group may include a hydrocarbon group as a substituent.

Examples of the alkyl group include an alkyl group which may include branches of 1 to 20 carbon atoms, may include a phenyl group as a substituent, and may include a heteroatom.

Examples of the heteroatom which may be included in R include an oxygen atom, a nitrogen atom, a sulfur atom, and a silicon atom. The heteroatom is preferably contained in the aryl group. It is preferable that R be a hydrocarbon group including no heteroatom in terms of structural stability and easy adsorption to the silicon nitride and the silicon oxide.

When R includes an aryl group, it is preferable that a carbon atom constituting the aryl group be bonded to an oxygen atom of —O-(AO)ₙ—H in terms of adsorption to the silicon nitride or the silicon oxide and adsorption to the silicon surface.

In regard to R, C1/(C1+C2)≥0.4 holds, where C1 is the number of atoms constituting the conjugated system and C2 is the number of atoms not constituting the conjugated system among the atoms (carbon atoms+heteroatoms) constituting the carbon skeleton. Since the proportion of atoms constituting the conjugated system is 40% or more, the adsorbability to the silicon nitride or the silicon oxide is excellent. The upper limit of C1/(C1+C2) may be 1 or less, preferably 0.9 or less, and more preferably 0.8 or less.

The oxyalkylene group of the AO includes an oxyalkylene group including 1 to 6 carbon atoms, and is preferably an oxyethyl group (—OCH₂CH₂—) or an oxypropyl group (—OCH₂CH₂CH₂— or —OCH₂CH(CH₃)—), more preferably an oxyethyl group, in terms of hydrophilicity and adsorbability on the silicon surface. The number n of repeating units of AO may be 2 to 200. In terms of hydrophilicity and adsorbability to the silicon surface, the number n of repeating units of AO is preferably 5 or more, and more preferably 10 or more. On the other hand, n is preferably 200 or less, preferably 180 or less, and more preferably 150 or less from in terms of ease of manufacture.

The compound (1) preferably has an HLB value of 12 to 20. When the HLB value is 12 or more, the compound (1) is stably dispersed or dissolved in water, and therefore the compound (1) is excellent in uniformity in the polishing material. In the present disclosure, the HLB value obtained by the Griffin method is used, and when the compound (1) is a combination of two or more compounds, an average value of the two or more compounds is used.

Preferred examples of the compound (1) include the following compounds. AO and n in the following chemical formula are the same as those in Formula (1). Note that C1/(C1+C2) of a compound (1-1) is 0.4, C1/(C1+C2) of a compound (1-2) is 0.8, and C1/(C1+C2) of a compound (1-3) is 1.

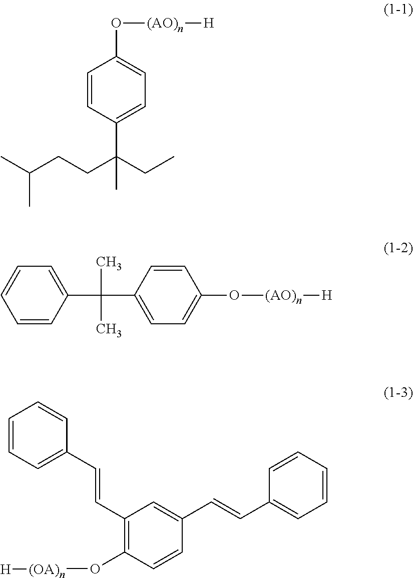

The compound (1) may be obtained synthetically or commercially available compound may be used. As an example, the compound (1) can be obtained by addition polymerization of alkylene oxide such as ethylene oxide or propylene oxide to the following compound (2). R in Formula (2) is the same as that in Formula (1), and the preferred embodiment is the same.

R—OH Formula (2)

The content rate of the compound (1) in the present polishing material is preferably 0.001 mass % to 1 mass %, more preferably 0.005 mass % to 0.5 mass % based on the entire polishing material. The polishing rate of the silicon is sufficiently controlled by setting the content of the compound (1) in the present polishing material to 0.001 mass % or more. At the same time, when the content of the compound (1) in the present polishing material is 1 mass % or less, the present polishing material can have excellent dispersibility and dispersion stability of the abrasive grains.

### <Abrasive Grain>

The present polishing material contains the abrasive grains. The abrasive grains may be appropriately selected from those used as abrasive grains for the CMP. In terms of the excellent polishing rate of the silicon nitride and the silicon oxide, the abrasive grains are preferably metal oxide particles.

The metal oxide includes a metal oxide selected from the group consisting of cerium oxide, alumina, silica, titania, and zirconia. Cerium oxide is preferable in terms of the excellent polishing rate of the silicon nitride and the silicon oxide.

Cerium oxide particles for the abrasive grains may be appropriately selected from known ones. Examples of the known cerium oxide particles include cerium oxide particles manufactured by the methods described in Japanese Unexamined Patent Application Publication No. H11-12561, Japanese Unexamined Patent Application Publication No. 2001-35818, and Published Japanese Translation of PCT International Publication for Patent Application, No. 2010-505735. Specifically, examples of the cerium oxide particles include cerium oxide particles obtained by adding an alkali to an aqueous solution of ammonium cerium (IV) nitrate to prepare a cerium hydroxide gel, and filtering, washing, and baking the gel; cerium oxide particles obtained by pulverizing and then baking high-purity cerium carbonate, and further pulverizing and classifying the high-purity cerium carbonate; and cerium oxide particles obtained by chemically oxidizing a cerium (III) salt in a liquid.

The average particle diameter of the metal oxide particles is preferably 0.01 to 0.5 μm, and more preferably 0.03 to 0.3 or less. When the average particle diameter is 0.5 μm or less, generation of polishing flaws such as scratches on the surface to be polished is prevented or minimized. When the average particle diameter is 0.01 μm or more, coarse agglomeration of particles is prevented or minimized, and the storage stability of the polishing material becomes excellent, and the polishing rate also becomes excellent. Since the metal oxide particles are present as aggregated particles (secondary particles) in which the primary particles are aggregated in the liquid, the preferred particle size of the metal oxide particles is expressed by the average secondary particle diameter. That is, the average particle diameter showing the above numerical value range is usually the average secondary particle diameter. The average secondary particle diameter is measured using a dispersion liquid in which the metal oxide particles are dispersed in a dispersion medium such as pure water by using a particle size distribution meter such as a laser diffraction/scattering type particle size distribution meter.

The content rate (concentration) of the abrasive grains is preferably 0.05 to 2.0 mass % and more preferably 0.10 to 0.5 mass % based on the entire polishing material. When the content rate of the abrasive grains is equal to or higher than the above-mentioned lower limit value, an excellent polishing rate can be obtained. On the other hand, if the content rate of the abrasive grains is equal to or less than the above-mentioned upper limit value, the increase in the viscosity of the present polishing material is prevented or minimized and the handling property is excellent.

### <Dispersion Medium>

The present polishing material is preferably used in a slurry state, and in this case, usually contains a dispersion medium. The dispersion medium may be suitably selected from those which are liquid at least at ordinary temperature (25° C.), can disperse or dissolve the compound (1), and can satisfactorily disperse the abrasive grains. In terms of the excellent handleability of the polishing material, water is preferably used as the dispersion medium.

### <Other Components>

The present polishing material may further contain other components within a range that exhibits the effects of the present disclosure. The other components include a pH adjuster, a dispersant, a lubricant, a polymer, etc.

The dispersant is used as needed to improve the dispersibility and dispersion stability of colloids of the abrasive grains. Examples of the dispersant include anionic, cationic, nonionic, amphoteric surfactants, and anionic, cationic, nonionic, amphoteric polymer compounds, and may contain one or more of these components.

The lubricant is used as needed to improve the lubricity of the polishing material and the in-plane uniformity of the polishing rate. Examples of the lubricant include water-soluble polymers such as polyethylene glycol and polyglycerol.

### (Polymer)

The present polishing material may contain a polymer. By the polymer being absorbed to the abrasive grains or the surface to be polished, the chemical interaction between the abrasive grains and the surface to be polished is prevented or minimized, and the polishing rate of the silicon nitride or the silicon oxide can be controlled. This effect makes it possible to properly control the polishing rate and to prevent or minimize dishing generated in the silicon nitride film or the silicon oxide film after the silicon surface is exposed on the surface.

The polymer may be appropriately selected from those exhibiting the above effects and may be used alone or in combination of two or more kinds of polymers. In particular, an anionic polymer is preferable among various kinds of polymers, because an anionic polymer can reduce the polishing rate of silicon more.

The anionic polymer is preferably a polymer including an acidic group. Examples of the acidic group include a sulfo group, a phospho group, a carboxy group, or a salt thereof. When the polishing target is the silicon oxide film, a carboxy group is preferable, while when the polishing target is the silicon nitride film, a sulfo group or a phospho group is preferable, because the ionized state of a sulfo group or a phospho group is stabilized even under strong acid.

The anionic polymer preferably includes an aryl group. The anionic polymer including an aryl group is presumed to be adsorbed to the film surface by the interaction of π electrons of the aryl group with the silicon nitride or the silicon oxide to be polished. Thus, the dishing of the silicon nitride film or the silicon oxide film is prevented or minimized. Furthermore, in the present polishing material, it is presumed that the dishing of the silicon nitride film or the silicon oxide film is further prevented or minimized by π-π stacking of the aryl group included in the anionic polymer and the conjugated system included in the compound (1).

The aryl group of the anionic polymer may be an aromatic hydrocarbon ring group such as a phenyl group, a naphthyl group, an anthracenyl group, and a pyrenyl group, or may be an aromatic heterocyclic group such as a furyl group, a thiophenyl group, and a pyridyl group. A phenyl group or a naphthyl group is preferable in terms of preventing or minimizing the dishing of the silicon nitride film or the silicon oxide film by interacting with the compound (1).

Specific example of the anionic polymer include polyacrylic acid; styrene acrylic acid copolymer; styrene maleic acid copolymer; copolymer of 2-acrylamide-2-methylpropanesulfonic acid and acrylic acid; copolymer of 2-acrylamide-2-methylpropanesulfonic acid and maleic acid; copolymer of 3-allyloxy-2-hydroxy-1 propanesulfonic acid and acrylic acid; copolymer of 3-allyloxy-2 hydroxy-1 propanesulfonic acid and maleic acid; copolymer of 2-acrylamide-2 methylpropanesulfonic acid, 3-allyloxy-2-hydroxy-1-propanesulfonic acid and maleic acid; copolymer of acrylic acid; copolymer of 2-acrylamide-2-methylpropanesulfonic acid, 3-allyloxy-2-hydroxy-1-propanesulfonic acid and maleic acid; copolymer of maleic acid; sulfonic acid modified product of polyvinyl alcohol; styrenesulfonic acid and maleic acid copolymer; styrenesulfonic acid and styrene copolymer; naphthalenesulfonic acid formalin condensate; and poly(p-styrenesulfonic acid). Among these compounds, a polymer containing a sulfo group is preferable, and styrene sulfonic acid maleic acid copolymer; naphthalenesulfonic acid formalin condensate, or poly(p-styrenesulfonic acid) are more preferable, and naphthalenesulfonic acid formalin condensate or poly(p-styrenesulfonic acid) are further more preferable.

The anionic polymer can be used alone or in combination of two or more kinds of the anionic polymers.

When a polymer is used for the present polishing material, the content rate of the polymer is preferably 0.0001 to 1 mass % based on the entire polishing material. Since the influence on the polishing rate of the silicon oxide film or the silicon nitride film greatly differs depending on the type of the polymer, in practice, the amount of the polymer is adjusted so as to achieve a predetermined polishing rate.

### (pH Adjuster)

The present polishing material may contain a pH adjuster to adjust the pH. The pH adjuster may be appropriately selected from known inorganic acids, organic acids, basic compounds, amphoteric compounds such as amino acids, and salts thereof.

Examples of the inorganic acid include nitric acid, sulfuric acid, hydrochloric acid, phosphoric acid, etc. and an ammonium salt thereof, a sodium salt thereof, a potassium salt thereof, etc. may be used as the inorganic acid.

Examples of the organic acid include carboxylic acids, organic sulfonic acids, organic phosphates, etc. and an ammonium salt thereof, a sodium salt thereof, a potassium salt thereof, etc. may be used as the organic acid.

Examples of the carboxylic acids include acetic acid, propionic acid, lactic acid, tartaric acid, oxalic acid, maleic acid, etc. Examples of the organic sulfonic acids include benzenesulfonic acid and tosylic acid. Examples of the organic phosphoric acids include methylphosphonic acid and dimethylphosphinic acid.

Examples of the basic compound include ammonia, potassium hydroxide, tetramethylammonium hydroxide, and ethylenediamine.

Examples of the amphoteric compound include glycine, alanine, and phenylalanine.

Since the present polishing material is preferably used under an acidic condition as described later, the pH adjuster is preferably an acidic substance. In order to provide pH buffering capability, it is preferable to use acid having pKa close to the pH range in which the polishing material is used, and in this sense, carboxylic acid, phosphonic acid, and phosphoric acid are preferable. Among them, phosphoric acid is preferable for improving the polishing rate of the silicon nitride film.

The content rate of the pH adjuster may be appropriately adjusted to a desired pH. As an example, the content rate of the pH adjuster may be 0.005 to 2.0 mass % based on the entire polishing material, preferably 0.01 to 1.5 mass %, and preferably 0.01 to 0.3 mass %.

The pH of the present polishing material is preferably 7 or less, and more preferably 2 to 7. By setting the pH to 7 or less, the polishing rate of the silicon nitride film and the silicon oxide film is improved, and the dispersion stability of the metal oxide particles as the abrasive grains is also improved. Within the above range, the pH of the present polishing material is preferably 2 to 6, and more preferably 2.0 to 5.5. Particularly, when the silicon nitride film is to be polished, it is preferable that the silicon nitride film be strongly acidic with pH of 2.0 to 3.5 in order to promote hydrolysis of the silicon nitride film.

### <Method for Preparing the Present Polishing Material>

The method for preparing the present polishing material may be appropriately selected from methods in which each component that can be contained in the polishing material is uniformly dispersed or dissolved in the dispersion medium.

For example, the present polishing material may be adjusted by adding the abrasive grains, the compound (1), and, as necessary, other components to the dispersion medium and stirring the mixture, or the dispersion liquid of the abrasive grains and the compound (1) solution may be prepared and then mixed. The mixing may be performed in a polishing device.

### <Polishing Method Using the Present Polishing Material>

An example of a polishing method using the present polishing material includes a method in which the surface of the polishing target to be polished is brought into contact with a polishing pad while the polishing material is supplied, and polishing is performed by relative motions of the surface to be polished and the polishing pad. Here, examples of the surface to be polished include a blanket wafer in which a silicon dioxide film or a silicon nitride film is formed on a front surface of a semiconductor substrate, and a patterned wafer in which a silicon dioxide film and a silicon nitride film are arranged in a pattern.

When the silicon nitride film or the silicon oxide film is polished using the present polishing material, the silicon surface of the semiconductor substrate functions as a stopper film. The silicon surface may be a single crystal of silicon, polysilicon, or amorphous silicon. By using the present polishing material, polishing can be suppressed even for polysilicon and amorphous silicon which has been relatively easy to be polished. According to the polishing material, for example, even if the silicon surface is a patterned wafer of polysilicon or amorphous silicon, the amount of polishing of the silicon surface can be controlled to 10 Å or less.

An example of the silicon dioxide film in the substrate for STI includes a so-called PE-TEOS film formed by plasma a CVD method using tetraethoxysilane (TEOS) as a raw material. An example of the silicon dioxide film includes a so-called HDP film formed by a high-density plasma CVD method. In addition, an HARP film or an FCVD film formed by other CVD methods and an SOD film formed by spin coating may also be used. Examples of the silicon nitride film include a film formed by a low-pressure CVD method or the plasma CVD method using silane or dichlorosilane and ammonia as raw materials, and a film formed by an ALD method.

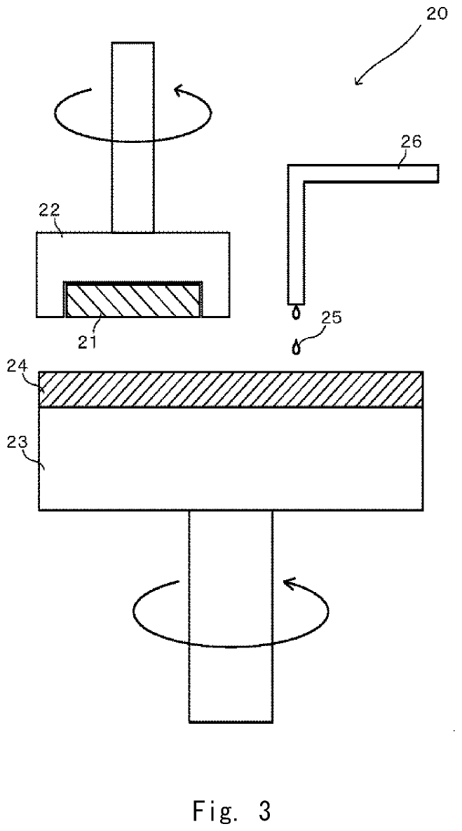

A known polishing device can be used in the polishing method according to the embodiment of the present disclosure. FIG. 3 is a schematic view showing an example of the polishing device. A polishing device 20 shown in the example of FIG. 3 includes a polishing head 22 for holding a semiconductor substrate 21 such as an STI substrate, a polishing surface plate 23, a polishing pad 24 attached to a surface of the polishing surface plate 23, and a polishing material supply pipe 26 for supplying a polishing material 25 to the polishing pad 24. The polishing device 20 is configured to perform polishing by bringing the surface of the semiconductor substrate 21 to be polished held by the polishing head 22 into contact with the polishing pad 24 and relatively rotating the polishing head 22 and the polishing surface plate 23 while supplying the polishing material 25 from the polishing material supply pipe 26.

The polishing head 22 may perform not only rotational motions but also linear motions. Further, the polishing surface plate 23 and the polishing pad 24 may have a size equal to or smaller than that of the semiconductor substrate 21. In this case, it is preferable that the polishing head 22 and the polishing surface plate 23 be moved relatively to polish the entire surface of the semiconductor substrate 21 to be polished. Furthermore, the polishing surface plate 23 and the polishing pad 24 may be, for example, a belt and may not be rotated and instead may be moved in one direction.

Although the polishing conditions of the polishing device 20 are not particularly limited, the polishing pressure can be further increased and the polishing rate can be improved by applying a load to the polishing head 22 and pressing it against the polishing pad 24. The polishing pressure is preferably about 0.5 to 50 kPa, and more preferably about 3 to 40 kPa in terms of preventing polishing defects such as uniformity, flatness, and scratches in the surface of the semiconductor substrate 21 to be polished at the polishing rate. The rotational speeds of the polishing surface plate 23 and the polishing head 22 are preferably about 50 to 500 rpm. A supply amount of the polishing material 25 is appropriately adjusted according to the composition of the polishing material, the polishing conditions, and the like.

The polishing pad 24 may be made of a nonwoven fabric, a foamed polyurethane, a porous resin, a nonporous resin, etc. In order to facilitate the supply of the polishing material 25 to the polishing pad 24 or to allow a certain amount of the polishing material 25 to accumulate in the polishing pad 24, the surface of the polishing pad 24 may be grooved in a grid pattern, a concentric pattern, a spiral pattern, or the like. If necessary, a pad conditioner may be brought into contact with the surface of the polishing pad 24 to perform the polishing while conditioning the surface of the polishing pad 24.

### EXAMPLE

Hereinafter, the present disclosure will be specifically described with reference to examples and comparative examples, but the present disclosure is not limited to these examples. In the following examples, “%” means % by mass unless otherwise specified. The characteristic values were measured and evaluated by the following method. Examples 1 to 5 are examples and an example 6 is a comparative examples.

[pH]

The pH was measured using a pH meter HM-30 R manufactured by Toa DKK Corporation.

### [Polishing Characteristics]

The polishing characteristics were evaluated by performing the following polishing using a full-automatic CMP polishing device (the apparatus name: Mirra, manufactured by Applied Materials Inc.). A two-layer polyurethane pad (with a ShoreD value of 65) was used as the polishing pad, and a CVD diamond pad conditioner (product name: Pyradia 179B, manufactured by Kinik Company) was used for conditioning the polishing pad. As the polishing conditions, the polishing pressure was 21 kPa, the rotational speed of the polishing surface plate was 77 rpm, and the rotational speed of the polishing head was 73 rpm. The supply rate of the polishing material was 200 ml/min.

### [Blanket Film]

In order to measure the polishing rate of the polysilicon film and the silicon nitride film, a blanket substrate in which polysilicon (poly-Si) is deposited and a blanket substrate in which silicon nitride (LP-SiN) is deposited were prepared on an 8-inch silicon wafer as polishing targets (an object to be polished).

### [Si Patterned Film]

In order to measure the polishing rate of the polysilicon film in the patterned film, a patterned wafer was prepared in which a stop layer was made of poly-Si and an LP-SiN film was formed in an STI pattern structure by the SEMATEC 864.

### [Polishing Rate Measuring Device]

A thickness gauge UV-1280SE of KLA-Tencor Corporation was used to measure the thicknesses of the blanket and patterned substrates.

### [Blanket Polishing Rate]

In the blanket substrate, the polishing rates of the polysilicon film and the silicon nitride film were calculated by obtaining a difference between the film thickness before the polishing and the film thickness after the polishing for 1 minute. An average value of the polishing rate (A per minute) obtained from the polishing rates of 49 points in the plane of the substrate was used as an evaluation index of the polishing rate.

### [Pattern Polishing Rate]

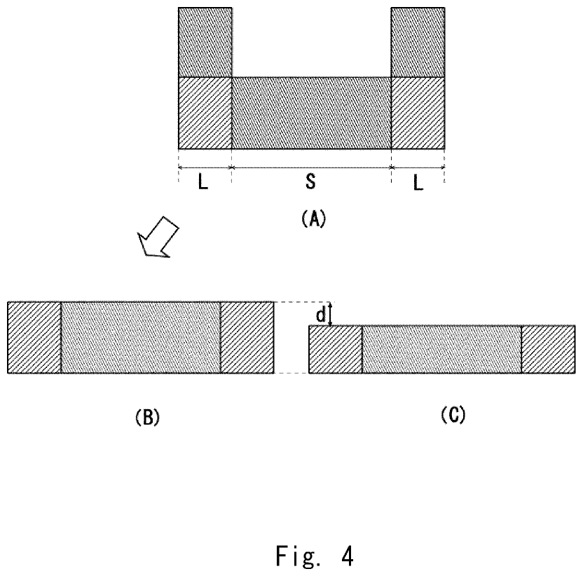

As a pattern substrate, as shown in FIG. 4A, a pattern having a width (L) of a line portion (polysilicon) of 10 μm and a width (S) of a space portion (silicon nitride) of 90 μm was prepared. This ratio of the lines to the spaces is a ratio at which polysilicon is easily ground, as a result of prior examination by the inventor. It was confirmed that the polysilicon film was exposed by removing the upper silicon nitride film and performing polishing in a step by step fashion until the polysilicon film was exposed (FIG. 4B). With the state shown in FIG. 4B as the initial state, additional polishing for 30 seconds was performed (FIG. 4C). The polishing rate of the polysilicon per minute was calculated from a change (d) in the film thickness of the polysilicon film in the polishing for 30 seconds.

### Example 1: Preparation of Polishing Material

Cerium oxide dispersion (hereinafter referred to as cerium oxide dispersion (a)) was prepared by dispersing cerium oxide particles having an average secondary particle diameter of 60 nm in pure water.

Then, pure cerium oxide was added to the cerium oxide dispersion (a) to prepare cerium oxide of 0.1 mass % based on the total amount of the polishing material. Then, polyoxyethylene (60) distyrylphenyl ether was added in an amount of 0.030 mass %, poly(p-styrenesulfonic acid) was added as an anionic polymer and stirred, and phosphoric acid was further added to adjust the pH to 2.5 to obtain a slurry-like polishing material (1). The poly(p-styrenesulfonic acid) was adjusted so that the polishing rate of the silicon nitride film becomes 600±50 Å/min.

### Examples 2 to 6: Preparation of Polishing Material

Polishing materials (2) to (6) of Example 2 to 6 were obtained in the same manner as in Example 1 except that the compound (1) and the anionic polymer were changed as shown in Table 1.

The polishing characteristics of the polishing materials (1) to (6) obtained in the above examples were measured by the above methods. The measurement results are shown in Table 1.

TABLE 1

| | | | C1/(C2 + C2) | Si [symbol] | Si | Si | | | |
|---|---|---|---|---|---|---|---|---|---|
| | | COMPOUND (1) | OF | BLANKET | BLANKET | PATTERN | | | |
| | ANIONIC | OR OTHER | COMPOUND | RATE | RATE | RATE | | | |
| | POLYMER | SURFACTANTS | (1), ETC. | R_{Si} [symbol] [Λ/min] | R_{Si}[Λ/min] | R_{SiP}[Λ/min] | R_{Si}/R_{Si} [symbol] | R_{SiP}/R_{Si} [symbol] | R_{SiP}/R_{Si} |
| EXAMPLE | POLY(P- | POLYOXY- | 1 | 630 | 8 | 8 | 1.3% | 1.3% | 100% |
| 1 | STYRENE- | ETHYLENE (60) | | | | | | | |
| | SULFONIC | DISTYRYL- | | | | | | | |
| | ACID) | PHENYL ETHER | | | | | | | |
| EXAMPLE | POLY(P- | POLYOXY- | 0.8 | 600 | 5 | 8 | 0.8% | 1.3% | 160% |
| 2 | STYRENE- | ETHYLENE (80) | | | | | | | |
| | SULFONIC | STYRYL- | | | | | | | |
| | ACID) | METHYL- | | | | | | | |
| | | PHENYL ETHER | | | | | | | |
| EXAMPLE | POLY(P- | POLYOXY- | 0.43 | 620 | 5 | 8 | 0.8% | 1.3% | 160% |
| 3 | STYRENE- | ETHYLENE (40) | | | | | | | |
| | SULFONIC | OCTYLPHENYL | | | | | | | |
| | ACID) | ETHER | | | | | | | |
| EXAMPLE | POLY(P- | POLYOXY- | 0.43 | 640 | 5 | 6 | 0.8% | 0.9% | 120% |
| 4 | STYRENE- | ETHYLENE (40) | | | | | | | |
| | SULFONIC | OCTYLPHENYL | | | | | | | |
| | ACID) | | | | | | | | |
| EXAMPLE | (ACRYLIC | ETHER | 0.43 | 650 | 6 | 14 | 0.9% | 2.2% | 233% |
| 5 | ACID/ | POLYOXY- | | | | | | | |
| | ACRYLAMIDO- | ETHYLENE (40) | | | | | | | |
| | METHYL | OCTYL- | | | | | | | |
| | PROPANE- | PHENYL | | | | | | | |
| | SULFONIC ACID) | ETHER | | | | | | | |
| | COPOLYMER | | | | | | | | |
| EXAMPLE | POLY(P- | POLYOXY- | 0 | 650 | 7 | 18 | 1.1% | 2.8% | 257% |
| 6 | STYRENE- | ETHYLENE (40) | | | | | | | |
| | SULFONIC ACID) | CETYL ETHER | | | | | | | |

[symbol]

indicates data missing or illegible when filed

As shown in Table 1, the polishing rate (Si blanket rate: R_{Si}) of the polysilicon blanket film is less than 10 Å/min in each of the Examples 1 to 6. However, the Si pattern rate (R_{SiP}) measured in the above-mentioned pattern polishing rate evaluation tended to be higher than that of R_{Si}. The use of the polishing materials of the Examples 1 to 5 containing the compound (1) was shown to prevent or minimize the increase in the Si pattern rate compared to the polishing material of the examples 6 containing other surfactants. In particular, the polishing materials of the Examples 1 to 4, in which anionic polymers including phenyl groups were used in combination, were found to significantly prevent or minimize the increase in the polishing rate of polysilicon in patterned wafers.

### INDUSTRIAL APPLICABILITY

Since the polishing rate of the silicon surface is controlled, the polishing material according to the present disclosure can be preferably used, for example, to expose a patterned surface including a silicon surface in a patterned wafer in which the silicon surface and a silicon oxide film or a silicon nitride film are arranged in a pattern. Therefore, the cerium oxide according to the present disclosure is suitable for planarizing an insulating film for STI in manufacturing a semiconductor device.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A polishing material comprising abrasive grains and a compound represented by a Formula (1).
R—O-(AO)ₘ—H Formula (1)
In the Formula (1), R is an organic group including a conjugated system and may include a heteroatom in a carbon skeleton, and C1/(C1+C2)≥0.4 holds, where C1 is the number of atoms constituting the conjugated system and C2 is the number of atoms not constituting the conjugated system among atoms constituting the carbon skeleton,
AO represents an oxyalkylene group, and a plurality of the AOs may be the same as or different from each other, and
n is an integer of 2 to 200.

2. The polishing material according to claim 1, wherein
the R includes an aryl group.

3. The polishing material according to claim 2, wherein
in an R—O bond of the Formula (1), an R-side atom is a carbon atom constituting the aryl group.

4. The polishing material according to claim 1, wherein
the R is a hydrocarbon group.

5. The polishing material according to claim 1, wherein
a compound expressed by the Formula (1) includes an HLB value of 12 to 20.

6. The polishing material according to claim 1, wherein
the abrasive grains are metal oxide particles.

7. The polishing material according to claim 1 further comprising a polymer.

8. The polishing material according to claim 7, wherein
the polymer comprises an anionic polymer.

9. The polishing material according to claim 8, wherein
the anionic polymer includes an aryl group.

10. The polishing material according to claim 1, wherein
pH is 2 to 7.

11. The polishing material according to claim 1 used to expose a patterned surface including a silicon surface on a surface.

12. A polishing method for bringing a surface to be polished into contact with a polishing pad while supplying a polishing material and performing polishing by a relative motion of the surface to be polished and the polishing pad, the polishing method comprising:
polishing the surface to be polished of a semiconductor substrate made of silicon oxide using the polishing material according to claim 1 as the polishing material.

13. The polishing method according to claim 12, wherein
a patterned surface including a silicon surface is exposed on a surface of the semiconductor substrate.
